(19) United States
(12) Patent Application Publication
(10) Pub. No.: US 2025/0115793 A1
(43) Pub. Date: Apr. 10, 2025

(54) HIGH HARDNESS, LOW VISCOSITY UV CURABLE POTTING ADHESIVE COMPOSITION

(71) Applicant: Henkel AG & Co. KGaA, Duesseldorf (DE)

(72) Inventors: Namdev Ghule, Navi Mumbai (IN); Krunal Trivedi, GIDC - Vapi (IN); Jayesh P. Shah, Pune (IN)

(21) Appl. No.: 18/984,273

(22) Filed: Dec. 17, 2024

Related U.S. Application Data
(63) Continuation of application No. PCT/EP2023/063500, filed on May 19, 2023.

(30) Foreign Application Priority Data
Jun. 17, 2022 (IN) 202241034861

(51) Int. Cl. C09J 163/10; C09J 11/06; C09J 11/08

(52) U.S. Cl. CPC C09J 163/10; C09J 11/06; C09J 11/08

(57) ABSTRACT

The present invention relates to an UV-curable adhesive composition comprising a) from 35 to 45% by weight of the total weight of the composition of a difunctional epoxy acrylate oligomer; b) a difunctional acrylate monomer; c) from 2 to 7% by weight of the total weight of the composition of a bridged difunctional acrylate monomer; d) an adhesion promoter; e) a stabiliser; f) a defoamer; and g) a photoinitiator. The composition can be used in a radio frequency identification transponder.

### TECHNICAL FIELD OF THE INVENTION

The present invention relates to an UV-curable adhesive composition comprising a difunctional epoxy acrylate oligomer, a difunctional acrylate monomer, a bridged difunctional acrylate monomer, an adhesion promoter, a stabiliser, a defoamer, and a photoinitiator. The composition according to the present invention has high hardness and low viscosity and is suitable for use in a radio frequency identification transponder.

### BACKGROUND OF THE INVENTION

In a fast-growing market of electronics, several delicate miniature/micro components are used for example RFID transponders which are utilised in various applications for identification, tracking, counterfeit protection etc. through chips or antennas.

RFID's transponders, antennas are delicate components which must be protected from physical and/or mechanical stress, and from dust contamination. To avoid such damages, the components are usually covered with potting adhesives exhibiting high hardness. Currently commercially used 2k epoxy adhesives show the high hardness property at moderate viscosity. However, 2k epoxy adhesives require extensive mixing and elevated temperature cure cycles, which ultimately effects on the process productivity, and therefore, does not meet the existing market demand.

To overcome the demerits of 2k epoxy adhesives, one-component UV curable adhesives are preferred since they can offer numerous advantages for instance cure speed, cure on demand, ease of handling and their ability to bond with different substrates.

UV curable adhesive which usually comprises of urethane, epoxy, acrylic esters deliver the key performance via radical polymerization. Reactive diluents like monofunctional and difunctional acrylate monomers are liable not only to reduce the viscosity but also to contribute to fine tuning of adhesive properties as per the application needs. Photoinitiator propels the photo radical polymerization in presences of UV light based on its absorption wavelength in nanometer (nm). UV curable adhesives also comprise various performance additives, defoamers and stabilizers for better handling and shelf-life stability.

Therefore, there is a need for an adhesive which provide good productivity, is able to be potted at high viscosity, and meets mixing and heat cure requirements for small delicate electronic components.

### BRIEF DESCRIPTION OF THE FIGURES

FIGS. 1a and 1b illustrates potted RFID and zinc enclosure and the same attached to an electric toothbrush.

FIGS. 2a and 2b illustrate potted and bonded RFIDs prepared from the composition according to example 2.

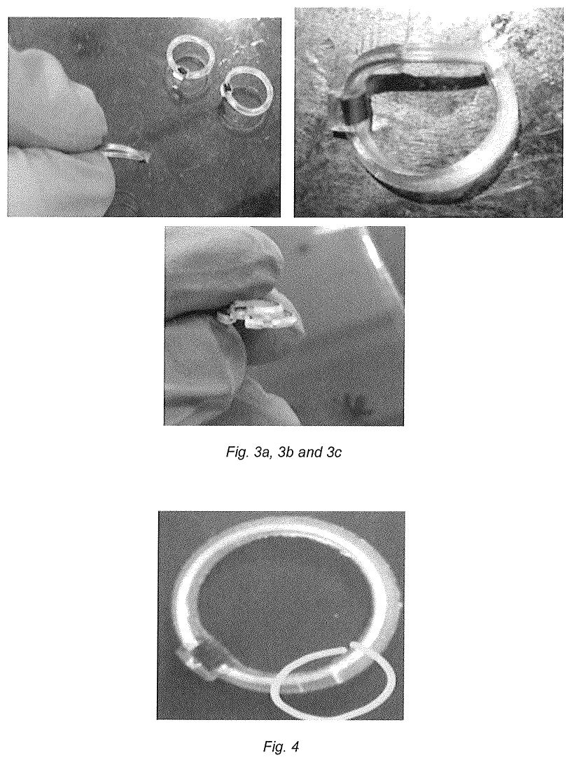

FIGS. 3a and 3b illustrate deformation before bonding and FIG. 3c illustrates deformation after the bonding.

FIG. 4 illustrates microcracks in a potted RFID.

### SUMMARY OF THE INVENTION

The present invention relates to an UV-curable adhesive composition comprising a) from 35 to 45% by weight of the total weight of the composition of a difunctional epoxy acrylate oligomer; b) a difunctional acrylate monomer; c) from 2 to 7% by weight of the total weight of the composition of a bridged difunctional acrylate monomer; d) an adhesion promoter; e) a stabiliser; f) a defoamer; and g) a photoinitiator.

The present invention also relates to a cured product comprising an UV-curable adhesive composition according to the present invention.

The present invention encompasses use of an UV-curable adhesive composition or a cured product according to the present invention in a radio frequency identification transponder.

### DETAILED DESCRIPTION OF THE INVENTION

In the following passages the present invention is described in more detail. Each aspect so described may be combined with any other aspect or aspects unless clearly indicated to the contrary. In particular, any feature indicated as being preferred or advantageous may be combined with any other feature or features indicated as being preferred or advantageous.

In the context of the present invention, the terms used are to be construed in accordance with the following definitions, unless a context dictates otherwise.

As used herein, the singular forms “a”, “an” and “the” include both singular and plural referents unless the context clearly dictates otherwise.

The terms “comprising”, “comprises” and “comprised of” as used herein are synonymous with “including”, “includes” or “containing”, “contains”, and are inclusive or open-ended and do not exclude additional, non-recited members, elements or method steps.

As used herein, the term “consisting of” excludes any element, ingredient, member or method step not specified.

The words “preferred”, “preferably”, “desirably” and “particularly” are used frequently herein to refer to embodiments of the disclosure that may afford particular benefits, under certain circumstances. However, the recitation of one or more preferable, preferred, desirable or particular embodiments does not imply that other embodiments are not useful and is not intended to exclude those other embodiments from the scope of the disclosure.

As used throughout this application, the word “may” is used in a permissive sense—that is meaning to have the potential to—rather than in the mandatory sense.

The recitation of numerical end points includes all numbers and fractions subsumed within the respective ranges, as well as the recited end points.

All percentages, parts, proportions and then like mentioned herein are based on weight unless otherwise indicated.

When an amount, a concentration or other values or parameters is/are expressed in form of a range, a preferable range, or a preferable upper limit value and a preferable lower limit value, it should be understood as that any ranges obtained by combining any upper limit or preferable value with any lower limit or preferable value are specifically disclosed, without considering whether the obtained ranges are clearly mentioned in the context.

As used herein, the term “one component (1K) composition” refers to a composition where, during storage of the composition, the composition components are all admixed together but the properties of the composition, including viscosity, remain consistent enough over the time of storage to permit successful utility of the composition at a later time.

“Two-component (2K) compositions” are understood to be compositions in which a first component/part and a second component/part must be stored in separate vessels because of their (high) reactivity. The two components/parts are mixed only shortly before application and then react, typically without additional activation, with bond formation and thereby formation of a polymeric network. Herein higher temperatures may be applied in order to accelerate the cross-linking reaction.

As used herein the term “Radio-frequency identification (RFID)” refers to a material that uses electromagnetic fields to automatically identify and track tags attached to objects. A RFID system consists of a tiny radio transponder, a radio receiver and transmitter. When triggered by an electromagnetic interrogation pulse from a nearby RFID reader device, the tag transmits digital data, usually an identifying inventory number, back to the reader.

All references cited in the present specification are hereby incorporated by reference in their entirety.

Unless otherwise defined, all terms used in disclosing the invention, including technical and scientific terms, have the meaning as commonly understood by one of the ordinary skilled in the art to which this invention belongs to. By means of further guidance, term definitions are included to better appreciate the teaching of the present invention.

The present invention relates to an UV-curable adhesive composition comprising a) from 35 to 45% by weight of the total weight of the composition of a difunctional epoxy acrylate oligomer; b) a difunctional acrylate monomer; c) from 2 to 7% by weight of the total weight of the composition of a bridged difunctional acrylate monomer; d) an adhesion promoter; e) a stabiliser; f) a defoamer; and g) a photoinitiator.

The composition according to the present invention provides high hardness at low viscosity solution for potting of from 0.5 to 1 mm thickness components. The composition can be cured fast without microcracks and air bubbles while providing good dimensional stability-no bending components. The composition further provides increased process productivity and energy savings compared to existing 2k epoxy adhesive solutions.

The UV-curable adhesive according to the present invention comprises a difunctional epoxy acrylate oligomer. The difunctional epoxy acrylate oligomer is used because it is a rigid molecule which provides high reactivity, hardness and excellent chemical and abrasion resistance, while has very low non-yellowing colour after cure.

Suitable difunctional epoxy acrylate oligomer may be selected from the group consisting of bisphenol A epoxy acrylate, difunctional bisphenol A epoxy acrylate, novolac epoxy acrylate, aromatic epoxy-modified acrylic resin, cresol novolac epoxy acrylate, and mixtures thereof, preferably the difunctional epoxy acrylate oligomer is bisphenol A epoxy acrylate.

Above preferred difunctional bisphenol A epoxy acrylates are all very rigid molecules which provide high reactivity, hardness and excellent chemical and abrasion resistance while having very low non-yellowing colour after cure.

Suitable commercially available difunctional epoxy acrylate oligomers for use in the present invention include but are not limited to epoxy acrylic prepolymer CN104 from Sartomer (Gz) Chemicals Ltd., Novolac epoxy acrylate (NAM-R205), Epoxy acrylate (NAM3000A) and Cresol Novolac epoxy acrylate (NAM-R9259) from Nagase America, Epoxy acrylate (Laromer 9019) from BASF and Epoxy acrylate (CN110 NS) and Epoxy acrylate (CN120 NS) from Sartomer.

The difunctional epoxy acrylate oligomer is present in the composition from 35 to 45% by weight of the total weight of the composition, preferably from 37 to 44% and more preferably from 39 to 43%.

If the quantity of a difunctional epoxy acrylate oligomer is higher than 45%, the overall viscosity of the product may increase towards higher side which could be difficult to dispense in potting of small components. Whereas the quantity of less than 35% may lead to a viscosity towards lower side, which may be easy for dispensing, however it may spread out of the potting mould and disturb the dimensions of the components.

The UV-curable adhesive according to the present invention comprises a difunctional acrylate monomer. The difunctional acrylate monomer act as a reactive diluent to tune the viscosity of the composition and it also offers flexible and hydrophobic nature to the composition.

Suitable difunctional acrylate monomer may be difunctional aliphatic acrylate monomer, preferably selected from the group consisting of hexanediol diacrylate, 1,4-butanediol diacrylate monomer, 1,12-dodecanediol diacrylate monomer, diethylene glycol diacrylate monomer, and mixtures thereof, preferably the difunctional acrylate monomer is hexanediol diacrylate.

Aliphatic difunctional acrylate monomers are preferred because they are flexible and clear in colour whereas, aromatic monomers tend to be rigid and promote yellowish colour.

Suitable commercially available a difunctional acrylate monomer for use in the present invention include but is not limited to hexanediol diacrylate SR238NS from Sartomer (Gz) Chemicals Ltd.

The difunctional acrylate monomer may be present in the composition from 40 to 50% by weight of the total weight of the composition, preferably from 42 to 48% and more preferably from 44 to 47%.

The above selected ranges may provide ideal viscosity to the composition.

The UV-curable adhesive according to the present invention comprises a bridged difunctional acrylate monomer. The bridged difunctional acrylate monomer provides non-yellowing, good flexibility and high Tg properties to the composition.

Preferably the bridged difunctional acrylate monomer is selected from the group consisting of tricyclodecane dimethanol diacrylate, isobornylmethacrylate, cyclohexane dimethanol diacrylate, and mixtures thereof, preferably the bridged difunctional acrylate monomer is tricyclodecane dimethanol diacrylate.

Tricyclodecane dimethanol diacrylate is especially preferred because it prevents/lower shrinkage of the component during cure. In addition, it also provides non-yellowing colour and good flexibility with high Tg properties to the composition.

Suitable commercially available bridged difunctional acrylate monomer for use in the present invention include but is not limited to tricyclodecane dimethanol diacrylate SR833NS from Sartomer (Gz) Chemicals Ltd.

The bridged difunctional acrylate monomer is present in the composition from 2 to 7% by weight of the total weight of the composition, preferably from 2.5 to 6%, and more preferably from 3 to 5%.

If the quantity of a difunctional acrylate monomer is higher than 7%, the overall viscosity of the product may increase too much which could lead difficulties in dispensing in small quantities and in addition, it may also negatively affect the desired hardness. Whereas less than 2% quantities may lead not to a desired hardness range.

The UV-curable adhesive according to the present invention comprises an adhesion promoter. Adhesion promoters act at the interface between an organic adhesive material and an organic/inorganic substrate to enhance adhesion between the two materials. The two materials often differ in ways that makes forming a strong adhesive bond between them difficult, e.g., differences in compatibility, chemical reactivity, surface properties, and coefficient of thermal expansion. An adhesion promoter acts to bond these dissimilar materials chemically and physically into a strong cohesive bond structure. Adhesion promoters can impart resistance to environmental and other destructive forces, such as heat and moisture, which often act on the bonded site to destroy adhesive strength.

Preferably, the adhesion promoter is selected from the group consisting of glycidoxypropyltrimethoxysilane, acrylic acid, γ-glycidoxy propyl trimethoxy silane, γ-glycidoxy ethyl trimethoxy silane, γ-glycidoxy methyl trimethoxy silane, γ-glycidoxy methyl triethoxy silane, γ-glycidoxy ethyl triethoxy silane, γ-glycidoxy propyl triethoxy silane; and 8-glycidooxy-n-octyl trimethoxysilane, and mixtures thereof, preferably the difunctional adhesion promoter is selected from the group consisting of glycidoxypropyltrimethoxysilane, acrylic acid and mixtures thereof.

Suitable commercially available adhesion promoters for use in the present invention include but are not limited to acrylic acid glacial from BASF and Silquest A 187 from Momentive.

The adhesion promoter may be present in the composition from 2 to 8% by weight of the total weight of the composition, preferably from 3 to 7%, and more preferably from 3.5 to 5.5%.

The above selected ranges provide ideal adhesion promotion, further, if the quantity of the adhesion promoter is more than 8%, it may negatively affect to the curing performance.

The UV-curable adhesive according to the present invention comprises a stabiliser. The stabiliser is used to inhibits the formation of peroxy radical intermediate.

Suitable stabiliser for use in the present invention may be selected from the group consisting of 2-tert-butylhydroquinone, butylhydroxytoluene, 1,4-benzoquinone, anthraquinone, hydroquinone, methoxyphenol-2,6-ditert-butyl-4-methoxy phenol, 4-tert-butylcatechol, and mixtures thereof, preferably the stabiliser is selected from 2-tert-butylhydroquinone, butylhydroxytoluene and mixtures thereof.

Suitable commercially available stabilisers for use in the present invention include but are not limited to 2-tert-butylhydroquinone from LOBA Chemie and butyl hydroxytoluene Topanol OC, from Azelis.

The stabiliser may be present in the composition from 0.01 to 0.1% by weight of the total weight of the composition, preferably from 0.02 to 0.09%, and more preferably from 0.04 to 0.08%.

The above selected ranges may provide ideal stabilisation to the composition without negatively affecting to the other properties.

The UV-curable adhesive composition according to the present invention comprises a defoamer. During preparation of the composition according to the present invention, a defoamer may be added into the composition during a dispersion process to reduce foaming.

Defoamers can be used which are also known in the field of detergents and cleaning agents for washing machines, dishwashers and the like and are available on the market for this purpose. The defoamer can be a non-silicone defoamer or silicone containing defoamer. In particular, defoamers containing non-ionic surfactants/polymers or silicon compounds with a defoaming effect are suitable as defoamers. For example, the latter can be selected from the group of oligo- or polysiloxanes, polyethersiloxanes, aminosiloxanes, alkoxylated siloxanes, siloxane copolymers and alkoxylation products thereof, siloxane glycol polymers and hydrophilically modified silicon compounds.

Any commercially available defoamer can be used in the composition according to the present invention. Suitable defoamer for use in the present invention can be for example silicone-free polymer air release agent. The defoamer may be selected from commercially available products, examples of which include but are not limited to TEGO Airex 990, TEGO Rad 2300 and TEGO Rad 2100 from Evonik; Wet 270 and Wet 500 from Evonik and BYK-A505, BYK-A530, BYK-A515 from BYK.

The defoamer may be present in the composition from 0.05 to 0.35% by weight of the total weight of the composition, preferably from 0.1 to 0.30%, and more preferably from 0.1 to 0.25%.

The applicant has found out that these quantities are preferred because higher quantities than 0.35% may adversely affect the coating performance, such as surface wettability. Whereas quantities lower than 0.05% may not provide desired defoaming effect.

The UV-curable adhesive composition according to the present invention comprises a photoinitiator. The photoinitiator acts to initiate the photopolymerization of chemically unsaturated oligomers in combination with mono- or multifunctional monomers.

Suitable photoinitiator for use in the present invention may be selected from the group consisting of hydroxyhexyl phenol ketone, 1-hydroxycyclohexyl phenyl ketone; benzophenone; 4-chlorobenzophenone; methyl 2-benzoylbenzoate; phenylbis(2,4,6-trimethylbenzoyl) phosphine oxide; diphenyl (2,4,6-trimethylbenzoyl) phosphine oxide; 4-phenylbenzophenone; 2-methyl-1-[4-ethylthio)phenyl]-2-(4-morpholinyl)-1-propanone; 2-hydroxy-4′-(2-hydroxyethoxy)-2-methyl propiophenone; 2,4-diethyl thioxanthone; thyl-4-(dimethylamino) benzoate; -(4′-methyl phenylthio)-benzophenone, and mixtures thereof, preferably the defoamer is 1-hydroxyhexyl phenol ketone.

Suitable commercially available photoinitiators for use in the present invention include but is not limited to Irgacure 184 from Ciba Speciality Chemicals.

The photoinitiator may be present in the composition from 1 to 10% by weight of the total weight of the composition, preferably from 2 to 8%, and more preferably from 3 to 5%.

The applicant has found out that these quantities are preferred because higher quantities than 10% may provide a tacky surface, whereas quantities lower than 1% may delay the cure.

The UV-curable adhesive composition according to the present invention has preferably a viscosity of from 80 to 140 cPs, wherein the viscosity is measured according to ASTM 4287 test method.

The Applicant has found that the above viscosity range is ideal. Generally, high viscosity adhesives do not work well for potting of small electronic components such as RFID, whereas low viscosity adhesive may easily flow and that may negatively effect on dimensions of the components. When the viscosity is too low, the composition may lose its dimensional stability and flatness of the potted components upon curing this may result in poor yield during final assembly and hairline cracks on edges.

The UV-curable adhesive composition according to the present invention has preferably refractive index equal or below 1.56. Refractive index is measured according to ASTM D1218-21.

Refractive index equal or below 1.56 is preferred because values below 1.56 provide composition with visual clarity.

The UV-curable adhesive composition according to the present invention has preferably halogen content below 1500 ppm. The halogen content is measured according to ASTM D4327-03.

Halogen content below 1500 ppm is preferred because that enables good electronic potting. In addition, the low content of halogens stimulates the resistance to corrosion and electromigration at high temperature and moisture. Further, the low content of halogens has advantages other than environmental aspects, such as halogen-free circuit boards have better dielectric breakdown ratings, lower coefficient of thermal expansion which enables higher operating temperature and lower moisture absorption rate.

The present invention also relates to a cured product comprising an UV-curable adhesive composition according to the present invention.

A cured product according to the present invention has a shore hardness from equal or higher than 82, wherein the shore hardness is measured according to ASTM 2240.

In a highly preferred embodiment, the cured product has the shore hardness is from 82 to 84.

The above hardness range have been found to be ideal, as the potting adhesive must require high hardness to protect small electronic components such as a radio frequency identification transponder from physical/mechanical stress and contamination.

According to the present invention the UV-curable adhesive composition and/or a cured product can be used in a radio frequency identification transponder.

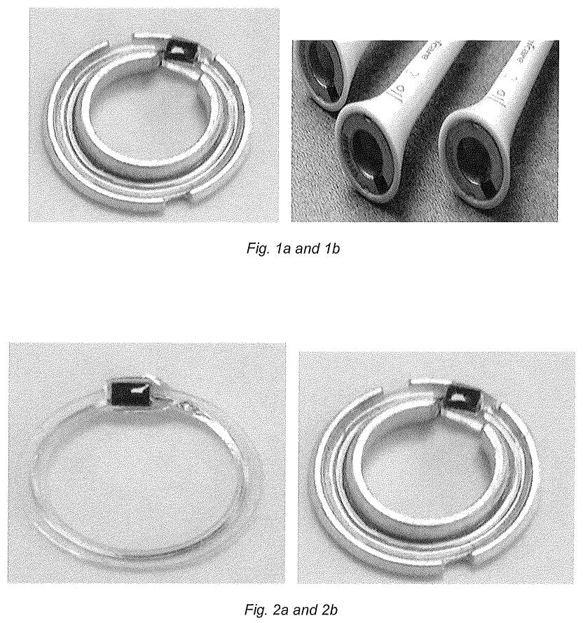

The potted RFIDs can be used for example in an electric toothbrush-potted RFID (potting has been done by using the composition according to the present invention) and zinc enclosure are illustrated in FIGS. 1a and 1b.

### Examples

### Test Methods

The shore D hardness was measured by preparing the sheets of 1.5 mm thickness. The sheets were prepared by UVA LOC1000 equipment under mercury lamp with 10 secs curing time. Four sheets were subsequently stacked top of one another to have required total thickness as per ASTM.

Viscosity was measured according to ASTM 4287 test method.

Examples according to the present invention were prepared and tested. Table 1 illustrates these compositions. Viscosity and shore D hardness were measured for the examples 1-2 according to the test methods described above and the results are exemplified in table 2 below.

TABLE 1

| | | Exam- | Exam- |
|---|---|---|---|
| Component | | ple 1 | ple 2 |
| Epoxy acrylate oligomer, | | 41.26 | 41.253 |
| epoxy acrylic prepolymer CN 104 from Sartomer | | | |
| (Gz) Chemicals Ltd | | | |
| Difunctional aliphatic acrylate monomer. | | 45.93 | 45.94 |
| hexane diol diacrylate, SR238 NS from Sartomer | | | |
| (Gz) Chemicals Ltd | | | |
| Bridged difunctional acrylate monomer, | | 4.00 | 4.00 |
| tricyclodecane dimethanol diacrylate SR833NS | | | |
| from Sartomer (Gz) Chemicals Ltd | | | |
| Adhesion | Acrylic acid | 3.00 | 3.00 |
| promoters | acrylic acid glacial, from BASF | | |
| | Glycidoxypropyl trimethoxy silane | 1.50 | 1.50 |
| | Silquest A 187 from Momentive | | |
| Fluorescent | Premix 11 (an optical brightener | 0.10 | 0.05 |
| active agent | agent dispersed in acrylate | | |
| | monomers) from Henkel Adhesive | | |
| | technology | | |
| Stabilizers | 2-tert-Butylhydroquinone from | 0.03 | 0.03 |
| | LOBA Chemie | | |
| | Butyl hydroxytoluene Topanol OC, | 0.03 | 0.03 |
| | from Azelis | | |
| Defoamer | Airex defoamer 990 | 0.15 | 0.19 |
| | Tego Airex 990, from Evonik | | |
| Photoinitiator | Hydroxy cyclohexyl phenyl ketone | 4.00 | 4.00 |
| | Irgacure 184 from Ciba Specialty | | |
| | Chemicals | | |
| Red pigment | Lithol Rubine in TPGDA (35% | — | 0.001 |
| | Lithol UV curable acrylate) from | | |
| | Pen Color | | |
| Yellow | Pigment yellow 14 in TPGDA (35% | — | 0.006 |
| pigment | yellow UV curable acrylate) from | | |
| | Pen Color | | |

| | | |
|---|---|---|
| Total | 100.00 | 100.00 |

TABLE 2

| | Properties | | | |
|---|---|---|---|---|
| | Viscosity | Shore D | Refractive | Halogen content |
| | (cPs) | hardness | index | (ppm) |
| Example 1 | 80-140 | 82-84 | | |
| Example 2 | 80-140 | 82-84 | 1.50 | 1400 |

Example 1 was prepared comprising the combination of epoxy acrylate and bridged difunctional aliphatic acrylate monomer, which later offered toughness and additionally worked as reactive diluents. Example 1 did not result in microcracks and deformation of dimension at low viscosity in a potting application of RFIDs (this is illustrated in FIG. 1).

Example 2 is the adhesive with addition of pigments (red & yellow) which appears amber in colour and having an ideal refractive index value of 1.50. Example 2 has halogens content of 1400 ppm which is within desired range. Further, Example 2 shows the same property performance as example 1 without compromising desired Shore D hardness and viscosity range.

Commercial samples LOCTITE AA3081 and LOCTITE AA3555 were used as a reference material.

LOCTITE® AA 3081™ is 1k UV curable modified acrylate and when uncured a transparent liquid. It has been designed for bonding cannula into hubs, syringes, and lancets. LOCTITE® AA 3081™ has excellent adhesion to glass, metal, and certain thermoplastic substrates. The ability of this product to fluorescence under black light facilitates inspection of bonded assemblies for adhesive. The low viscosity of this product makes it ideal for applications where wicking of the adhesive into pre-assembled parts is desired.

LOCTITE® AA 3555™ is 1k curable (visible light) acrylate urethane and when uncured a transparent yellow liquid with green tint. LOCTITE® AA 3555™ cures rapidly when exposed to visible light of sufficient intensity. The rapid cure characteristics make it ideal for potting applications which require a fast and large depth of cure. The ability of LOCTITE® AA 3555™ to fluoresce under black light facilitates inspection of bonded assemblies for adhesive presence. LOCTITE® AA 3555™ is suitable for a wide variety of applications that require bonding polycarbonate to itself and a variety of other substrates, while not inducing stress cracking under typical moulded stress levels.

Viscosity and shore D hardness were measured for LOCTITE AA3081 and LOCTITE AA3555 according to the test methods described above and the results are exemplified in table 3 below.

TABLE 3

Properties

| | Viscosity (cPs) | Shore D hardness |
|---|---|---|
| LOCTITE AA3081 | 100 | 74 |
| LOCTITE AA3555 | 1000 | 77 |

Following comparative examples were prepared and tested. The comparative examples 1-6 are illustrated in table 4 below. Viscosity and shore D hardness were measured for the comparative examples 1-6 according to the test methods described above and the results are exemplified in table 5 below.

TABLE 4

| | | Comp. | Comp. | Comp. | Comp. | Comp. | Comp. |
|---|---|---|---|---|---|---|---|
| Component | | ex. 1 | ex. 2 | ex. 3 | ex. 4 | ex. 5 | ex. 6 |
| Blended urethane acrylate | | 54.30 | 54.30 | | | 38.00 | |
| oligomer, urethane acrylate | | | | | | | |
| blend CN 970A6NS from | | | | | | | |
| Sartomer (Gz) Chemicals | | | | | | | |
| Ltd. | | | | | | | |
| Urethane acrylate oligomer, | | | | 20.00 | 20.00 | | 15.00 |
| urethane acrylate oligomer | | | | | | | |
| Flex III, from Henkel | | | | | | | |
| Adhesive technology | | | | | | | |
| Epoxy acrylate oligomer, | | | | | | 12.00 | 35.00 |
| epoxy acrylate prepolymer | | | | | | | |
| CN104 from Sartomer (Gz) | | | | | | | |
| Chemicals Ltd. | | | | | | | |
| Polyethylene glycol | | 8.80 | | | | | |
| methacrylate 400, PEGDMA | | | | | | | |
| 400 from Rohm (Evonik | | | | | | | |
| Degussa) | | | | | | | |
| Trifunctional acrylate | | | | 20.00 | 10.00 | | |
| monomer, | | | | | | | |
| trimethylpropanetriacrylate | | | | | | | |
| SR351NS from Sartomer | | | | | | | |
| (Gz) Chemicals Ltd. | | | | | | | |
| Cyclic acrylate monomer, | | | 8.80 | | | | |
| cyclic trimethylolpropane | | | | | | | |
| formal acrylate, M1110 from | | | | | | | |
| Miwon specialty chemicals | | | | | | | |
| Bridged monofunctional | | | | | | 41.69 | |
| acrylate monomer, isobornyl | | | | | | | |
| acrylate visiomer IBOMA | | | | | | | |
| from Evonik | | | | | | | |
| Bridged Difunctional | | 30.00 | 30.00 | 50.65 | 60.65 | | |
| acrylate monomer, | | | | | | | |
| tricyclodecane dimethanol | | | | | | | |
| diacrylate SR833NS from | | | | | | | |
| Sartomer (Gz) Chemicals | | | | | | | |
| Ltd. | | | | | | | |
| Difunctional aliphatic | | | | | | | 41.19 |
| acrylate monomer, | | | | | | | |
| hexanedioldiacrylate | | | | | | | |
| R238NS from Sartomer (Gz) | | | | | | | |
| Chemicals Ltd. | | | | | | | |
| Adhesion | Acrylic acid, | 3.00 | 3.00 | 3.00 | 3.00 | 3.00 | 3.00 |
| | acrylic acid | | | | | | |
| | glacial from | | | | | | |
| | BASF | | | | | | |
| promoters | Glycidoxy | | | 2.00 | 2.00 | 1.50 | 1.50 |
| | propyl | | | | | | |
| | trimethoxy | | | | | | |
| | silane, | | | | | | |
| | Silquest A | | | | | | |
| | 187 from | | | | | | |
| | Momentive | | | | | | |
| Fluorescent | Premix 11 (an | 0.10 | 0.10 | | | | |
| active | optical | | | | | | |
| agent | brightener | | | | | | |
| | agent | | | 0.10 | 0.10 | 0.10 | 0.10 |
| | dispersed in | | | | | | |
| | acrylate | | | | | | |
| | monomers) | | | | | | |
| | from Henkel | | | | | | |
| | Adhesive | | | | | | |
| | technology | | | | | | |
| | from Henkel | | | | | | |
| | Adhesive | | | | | | |
| | technology | | | | | | |
| Stabilizers | 2-tert-butyl | | | 0.10 | 0.10 | 0.03 | 0.03 |
| | hydroquinone | | | | | | |
| | from LOBA | | | | | | |
| | Chemie | | | | | | |
| | Butyl hydroxy | | | | | 0.03 | 0.03 |
| | toluene, | | | | | | |
| | Topanol OC | | | | | | |
| | from Azelis | | | | | | |
| Defoamer | Airex | | | 0.15 | 0.15 | 0.15 | 0.15 |
| | defoamer 990 | | | | | | |
| | Tego Airex | | | | | | |
| | 990 from | | | | | | |
| | Evonik | | | | | | |
| Photo- | Hydroxy | 3.80 | 3.80 | 4.00 | 4.00 | 3.50 | 4.00 |
| initiator | cyclohexyl | | | | | | |
| | phenyl | | | | | | |
| | ketone, | | | | | | |
| | Irgacure 184 | | | | | | |
| | from Ciba | | | | | | |
| | Specialty | | | | | | |
| | Chemicals | | | | | | |

| | | | | | | |
|---|---|---|---|---|---|---|
| Total | 100.00 | 100.00 | 100.00 | 100.00 | 100.00 | 100.00 |

TABLE 5

| | Properties | |
|---|---|---|
| | Viscosity (cPs) | Shore D hardness |
| Comparative example 1 | 250-280 | 60-62 |
| Comparative example 2 | 240-255 | 68-69 |
| Comparative example 3 | 265-280 | 81-82 |
| Comparative example 4 | 220-230 | 80-81 |
| Comparative example 5 | 200-235 | 65-68 |
| Comparative example 6 | 169-180 | 78-80 |

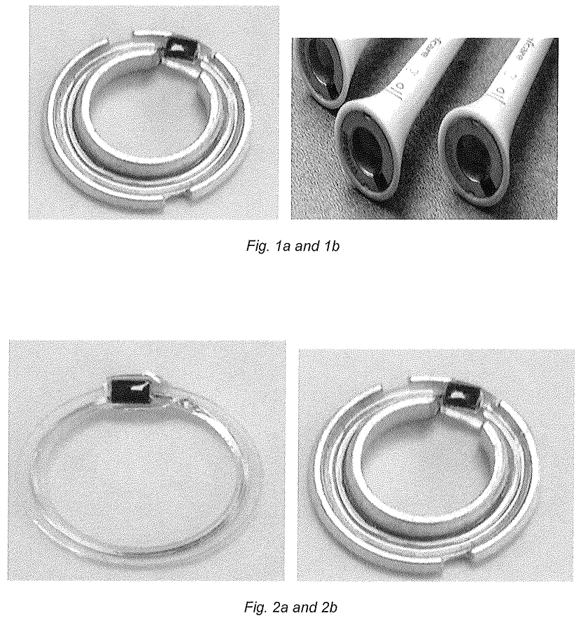

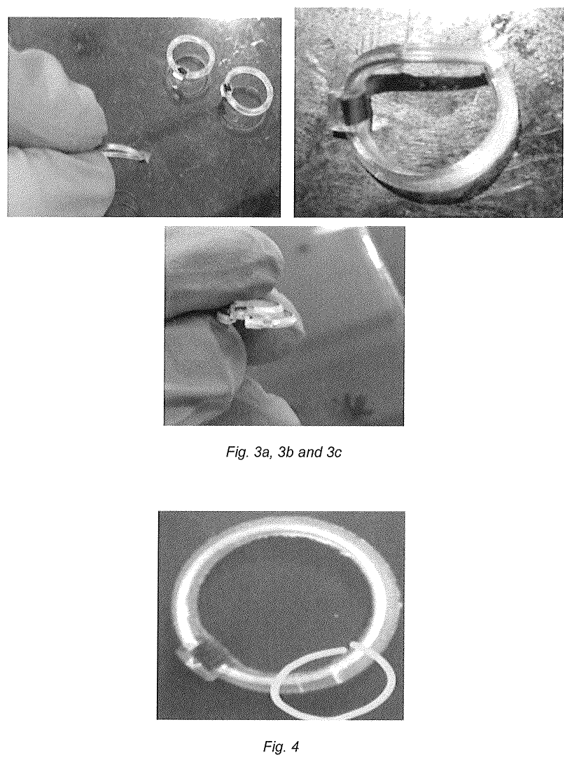

Comparative examples 1 and 2 comprised the urethane acrylate oligomers, mono and multifunctional acrylate reactive diluents, additives, stabilizers and photoinitiators. The viscosity, appearance and curing speed were within desired values, however, the shore D hardness was <80 owing to flexible nature of the backbone of the used polymers. Comparative examples 3 and 4 comprised trifunctional acrylate monomer and bridged difunctional acrylate monomers, which resulted the shore D hardness >80, however microcracks were observed after curing of RFID components due to high cross-linking density of the reactive diluents. Comparative examples 5 and 6 comprised a combination of urethane acrylate and epoxy acrylate oligomers with reactive diluents, which resulted in not desired Shore D hardness. FIGS. 3a and 3b illustrate deformation before bonding and FIG. 3c illustrates deformation after the bonding, which is due too soft material. FIG. 4 illustrates microcracks in a potted RFID, which is resulted in due high cross-linking density.

What is claimed is:

1. An UV-curable adhesive composition comprising
a) from 35 to 45% by weight of the total weight of the composition of a difunctional epoxy acrylate oligomer;
b) a difunctional acrylate monomer;
c) from 2 to 7% by weight of the total weight of the composition of a bridged difunctional acrylate monomer;
d) an adhesion promoter;
e) a stabiliser;
f) a defoamer; and
g) a photoinitiator.

2. The UV-curable adhesive composition according to claim 1, wherein the difunctional epoxy acrylate oligomer is selected from the group consisting of bisphenol A epoxy acrylate, difunctional bisphenol A epoxy acrylate, novolac epoxy acrylate, aromatic epoxy-modified acrylic resin, cresol novolac epoxy acrylate, and mixtures thereof.

3. The UV-curable adhesive composition according to claim 1, wherein the difunctional acrylate monomer is difunctional aliphatic acrylate monomer selected from the group consisting of hexanedioldiacrylate, 1,4-butanediol diacrylate monomer, 1,12-dodecanediol diacrylate monomer, diethylene glycol diacrylate monomer, and mixtures thereof.

4. The UV-curable adhesive composition according to claim 1, wherein the bridged difunctional acrylate monomer is selected from the group consisting of tricyclodecane dimethanoldiacrylate, isobornylmethacrylate, cyclohexane dimethanol diacrylate, and mixtures thereof.

5. The UV-curable adhesive composition according to claim 1, wherein the adhesion promoter is selected from the group consisting of glycidoxypropyltrimethoxysilane, acrylic acid, γ-glycidoxy propyl trimethoxy silane, γ-glycidoxy ethyl trimethoxy silane, γ-glycidoxy methyl trimethoxy silane, γ-glycidoxy methyl triethoxy silane, γ-glycidoxy ethyl triethoxy silane, γ-glycidoxy propyl triethoxy silane; and 8-glycidooxyoctyl trimethoxysilane, and mixtures thereof.

6. The UV-curable adhesive composition according to claim 1, wherein the stabiliser is selected from the group consisting of 2-tert-butylhydroquinone, butylhydroxytoluene, 1,4-benzoquinone, anthraquinone, hydroquinone, methoxyphenol-2,6-ditert-butyl-4-methoxy phenol, 4-tert-butylcatechol, and mixtures thereof.

7. The UV-curable adhesive composition according to claim 1, wherein the defoamer can be a non-silicone defoamer or silicone containing defoamer, preferably is selected from the group consisting of oligo- or polysiloxanes, polyethersiloxanes, aminosiloxanes, alkoxylated siloxanes, siloxane copolymers and alkoxylation products thereof, siloxane glycol polymers and hydrophilically modified silicon compounds, and mixtures thereof.

8. The UV-curable adhesive composition according to claim 1, wherein the photoinitiator is selected from the group consisting of hydroxyhexyl phenol ketone, 1-hydroxycyclohexyl phenyl ketone; benzophenone; 4-chlorobenzophenone; methyl 2-benzoylbenzoate; phenylbis(2,4,6-trimethylbenzoyl) phosphine oxide; diphenyl (2,4,6-trimethylbenzoyl) phosphine oxide; 4-phenylbenzophenone; 2-methyl-1-[4-ethylthio) phenyl]-2-(4-morpholinyl)-1-propanone; 2-hydroxy-4′-(2-hydroxyethoxy)-2-methyl propiophenone; 2,4-diethyl thioxanthone; thyl-4-(dimethylamino) benzoate; -(4′-methyl phenylthio)-benzophenone, and mixtures thereof.

9. The UV-curable adhesive composition according to claim 1, wherein the composition has a viscosity of from 80 to 140 cPs, wherein the viscosity is measured according to ASTM 4287 test method.

10. A cured product comprising an UV-curable adhesive composition according to claim 1.

11. The cured product according to claim 11, wherein the cured product has a shore hardness from equal or higher than 82, wherein the shore hardness is measured according to ASTM 2240.
